(19) United States
(12) Patent Application Publication
(10) Pub. No.: US 2008/0084808 A1
(43) Pub. Date: Apr. 10, 2008

(54) SUBMOUNT, SEMICONDUCTOR LASER DEVICE, MANUFACTURING METHOD THEREFOR, HOLOGRAM LASER DEVICE AND OPTICAL PICKUP DEVICE

(75) Inventor: Munesato KUMAGAI, Mihara-shi (JP)

Correspondence Address: MORRISON & FOERSTER LLP, 1650 TYSONS BOULEVARD, SUITE 400, MCLEAN, VA, 22102, US

(73) Assignee: Sharp Kabushiki Kaisha, Osaka (JP)

(21) Appl. No.: 11/866,066

(22) Filed: Oct. 2, 2007

(30) Foreign Application Priority Data
Oct. 5, 2006 (JP) 2006-274271

(51) Int. Cl. G11B 7/135; H01L 33/00; H01S 5/022

(52) U.S. Cl. 369/112.1; 372/50.1; 372/50.21; 438/26; 257/E33.063

(57) ABSTRACT

A submount of the present invention includes substrates made of a principal material of Si and impurity diffusion layers formed by diffusing an impurity into a region of a substrate surface above which a semiconductor laser chip is to be mounted. A TiW layer, an Au layer, a Pt layer and an AuSn layer are successively layered on the impurity diffusion layer. The thickness of the Pt layer is set so that the Pt layer remains in fusing the AuSn layer for bonding the semiconductor laser chip in accordance with the thickness of an Au electrode layer provided on the lower surface of the semiconductor laser chip, the thickness of the Au layer and the thickness and the composition ratio of the AuSn layer.

### CROSS-REFERENCE TO RELATED APPLICATIONS

This Nonprovisional application claims priority under 35 U.S.C. §119(a) on Patent Application No. 2006-274271 filed in Japan on Oct. 5, 2006, the entire contents of which are hereby incorporated by reference.

### BACKGROUND OF THE INVENTION

The present invention relates to a submount and, in particular, to a submount made of a principal material of Si.

The present invention also relates to a semiconductor laser device in which a semiconductor laser chip is bonded to such a submount and a manufacturing method therefor.

The present invention further relates to a hologram laser device and an optical pickup device having such a semiconductor laser device.

Conventionally, as a submount employed in a hologram laser device for DVD (Digital Versatile Disk), a device (denoted by reference numeral 100) as shown in FIG. 11A is known (refer to JP 2003-229633 A). The submount 100 has a light receiving element 103 (formed by diffusing a p-type impurity) for monitoring the output of a semiconductor laser chip fabricated on a surface 101a of an n-type Si substrate 101 (including an n⁻-epitaxial layer 102). Moreover, a p⁺ diffusion region 104 and an n⁺ diffusion region 105 are provided for preventing shortcircuit between the semiconductor laser chip and the submount 100 in a region of the substrate surface 101a above which the semiconductor laser chip is to be mounted. An SiN film 106 as a passivation film has an opening above the region, and a TiW layer 107, an Au layer 108 and an AuSn layer 109 are formed in order. It is noted that the AuSn layer 109 is a bonding material for bonding the semiconductor laser chip to be mounted on the layer. The Au layer 108 is provided for increasing adhesion to the AuSn layer 109. The TiW layer 107 is provided as a barrier metal for preventing the AuSn of the upper layer from diffusing to the substrate 101 side. An Al layer 110 serves as electric wiring.

As shown in FIG. 11B, a semiconductor laser chip 200 is bonded onto the AuSn layer 109 of the submount 100. The bonding step is carried out by fusing the AuSn layer 109 by heating the submount 100 to a temperature of about 280° C. to 400° C., making the semiconductor laser chip 200 closely adhere with pressurization to the layer from above and thereafter hardening the AuSn layer 109 by cooling them.

By thus bonding the semiconductor laser chip 200 to the submount 100, heat generated by the semiconductor laser chip 200 in operation is intended to radiate from the semiconductor laser chip 200 directly to the Si substrate 101 (and further to a heat sink (not shown)) without via the SiN film 106.

### SUMMARY OF THE INVENTION

However, since the Au layer 108 of the submount 100 rapidly diffuses into the AuSn layer 109 when the AuSn layer 109 is fused in the bonding step, it is sometimes the case where the Au layer 108 wholly dissolves into the AuSn layer 109 and disappears. The fused AuSn layer 109 has a poor conformability (wettability) with respect to the TiW layer 107, and therefore, the fused AuSn layer 109 is repelled on the TiW layer 107 and become granulated by surface tension as shown in FIG. 12 (this is denoted by reference numeral 109B). When the semiconductor laser chip 200 is pressurized from above and cooled to harden AuSn, a number of voids 130 are generated between the semiconductor laser chip 200 and the submount 100 as shown in FIG. 13. Accordingly, there is a problem that the substantial bonding area with respect to the submount 100 of the semiconductor laser chip 200 is reduced to impair heat radiation characteristic.

Moreover, generally in a stage in which the Au layer 108 (chemically stable) is formed on the substrate 101 by means of a sputtering apparatus and/or a vapor deposition apparatus in the process of manufacturing the submount 100 shown in FIG. 11A, the substrate 101 is once taken out into the atmosphere. One reason for the above is that providing the facilities with many kinds of targets and raw material sources and performing layer formation up to the AuSn layer 109 continuously (without unloading into the atmosphere) in an identical facility increase the facility scale leading to a high facility cost and complicate the facility control. Another reason is that the submount (denoted by reference numeral 100B in FIG. 14A) obtained from the substrate 101 that has undergone the layer formation up to the Au layer 108 is used in common for an inexpensive type (referred to as an “Ag paste type”) in which the semiconductor laser chip 200 is bonded with an Ag paste 111 as shown in FIG. 14B. Therefore, an adjustment is performed whether to store the substrate 101 that has undergone the layer formation up to the Au layer 108 and manufacture a submount 100 of a high heat radiation efficiency type by further forming an AuSn layer 109 on (the Au layer 108 of) the substrate 101 as occasion demands in view of manufacturing or to manufacture a submount 100B for the Ag paste type by dividing the substrate 101 as it is without forming the AuSn layer 109.

An object of the present invention is to provide a submount capable of stably bonding the whole area of the bonding surface of the semiconductor laser chip and using the substrate in common for the product of the Ag paste type by once unloading the substrate into the atmosphere in a stage in which the Au layer is formed in the manufacturing process.

Another object of the present invention is to provide a semiconductor laser device in which a semiconductor laser chip is bonded onto such a submount and a manufacturing method therefor.

Yet another object of the present invention is to provide a hologram laser device and an optical pickup device having such a semiconductor laser device.

In order to accomplish the objects, a submount of the present invention comprises:

a substrate made of a principal material of Si;

an impurity diffusion layer formed by diffusing an impurity in a region of a surface of the substrate above which a semiconductor laser chip is to be mounted;

an Au layer and an AuSn layer that are successively layered on the impurity diffusion layer;

a TiW layer that is interposed between the impurity diffusion layer and the Au layer and prevents diffusion of an element between the impurity diffusion layer and the Au layer and the AuSn layer; and

a Pt layer interposed between the Au layer and the AuSn layer, wherein

the Pt layer has a thickness set so that the Pt layer remains in fusing the AuSn layer for bonding the semiconductor laser chip in accordance with a thickness of the Au electrode layer provided on a lower surface of the semiconductor laser chip, a thickness of the Au layer and a thickness and a composition ratio of the AuSn layer.

It is noted that using Si as a “principal material” means permission of impurities diffusing in Si crystals.

In the submount of the present invention, the Pt layer is interposed between the Au layer and the AuSn layer. The substance of Pt has properties that it scarcely diffuses into the fused AuSn layer and is not fused at the normal heating temperature used to fuse the AuSn layer besides the property of good conformability to the fused AuSn layer and the TiW layer. However, diffusion to the fused AuSn layer occurs even in the case of Pt although it is very little in comparison to Au. Moreover, Au also diffuses through Pt. Accordingly, the thickness of the Pt layer is set so that the Pt layer remains in fusing the AuSn layer for bonding the semiconductor laser chip in accordance with the thickness of the Au electrode layer provided on the lower surface of the semiconductor laser chip, the thickness of the Au layer and the thickness and the composition ratio of the AuSn layer. In other words, the amount of diffusion of Pt from the Pt layer to the fused AuSn layer, to which the Au electrode layer provided on the lower surface of the semiconductor laser chip and the Au layer diffuse, is substantially determined depending on the total amount of Au on the Pt layer. Therefore, the thickness of the Pt layer is set so as to exceed the amount of diffusion of Pt.

As a result, it is possible to make the Pt layer remain on the TiW layer in fusing the AuSn layer for bonding the semiconductor laser chip (the Au layer also remains between the TiW layer and the Pt layer). Since Pt has properties that it has good conformability to the fused AuSn layer, the fused AuSn layer spreads flat without being granulated by surface tension on the remaining Pt layer. Therefore, the whole area of the bonding surface of the semiconductor laser chip can stably be bonded by pressurizing the semiconductor laser chip from above and hardening the AuSn by cooling the chip. That is, no void is generated between the impurity diffusion layer on the substrate surface of the submount and the semiconductor material of the semiconductor laser chip. Therefore, heat generated by the semiconductor laser chip in operation can efficiently be radiated from the semiconductor laser chip directly to the Si substrate. As a result, the effects of improving the lifetime of the semiconductor laser chip, improving the reliability of the semiconductor laser device and power savings are obtained.

Moreover, in the submount of the present invention, the structures of the Au layer and the lower layers can be made identical to those of the prior art example (see FIG. 11A). Accordingly, in the stage in which the Au layer (chemically stable) is formed by means of a sputtering apparatus and/or a vapor deposition apparatus in the process of fabricating the submount of the present invention, the substrate that has undergone the layer formation up to the Au layer is once unloaded into the atmosphere. If the substrate is stored, an adjustment becomes possible whether to manufacture the submount of the present invention (submount of a high heat radiation efficiency type) by further forming the Pt layer and the AuSn layer on (the Au layer of) the substrate as occasion demands in view of manufacturing or to manufacture a submount for the Ag paste type by dividing the substrate as it is without forming the AuSn layer. That is, the submount of the present invention can be used in common for the product of the Ag paste type. Moreover, since layer formation up to the AuSn layer is not continuously (without unloading into the atmosphere) performed on the substrate in an identical facility, the facility cost is not increased and the facility control does not become complicated.

In another aspect, a submount of the present invention is provided an Ni layer in place of the Pt layer, wherein

the Ni layer has a thickness set so that the Ni layer remains in fusing the AuSn layer for bonding the semiconductor laser chip in accordance with the thickness of the Au electrode layer provided on the lower surface of the semiconductor laser chip, the thickness of the Au layer and the thickness and the composition ratio of the AuSn layer.

The substance of Ni has properties that it scarcely diffuses into the fused AuSn layer and is not fused at the normal heating temperature used to fuse the AuSn layer besides the property of good conformability to the fused AuSn layer and the TiW layer. However, diffusion to the fused AuSn layer occurs even in the case of Ni although it is very little in comparison to Au. Moreover, Au also diffuses through Ni. Accordingly, the thickness of the Ni layer is set so that the Ni layer remains in fusing the AuSn layer for bonding the semiconductor laser chip in accordance with the thickness of the Au electrode layer provided on the lower surface of the semiconductor laser chip, the thickness of the Au layer and the thickness and the composition ratio of the AuSn layer. In other words, the amount of diffusion of Ni from the Ni layer to the fused AuSn layer, to which the Au electrode layer provided on the lower surface of the semiconductor laser chip and the Au layer diffuse, is substantially determined depending on the total amount of Au on the Ni layer. Therefore, the thickness of the Ni layer is set so as to exceed the amount of diffusion of Ni.

As a result, it is possible to make the Ni layer remain on the TiW layer in fusing the AuSn layer for bonding the semiconductor laser chip (the Au layer also remains between the TiW layer and the Ni layer). Since Ni has properties that it has good conformability to the fused AuSn layer, the fused AuSn layer spreads flat without being granulated by surface tension on the remaining Ni layer. Therefore, the whole area of the bonding surface of the semiconductor laser chip can stably be bonded by pressurizing the semiconductor laser chip from above and hardening the AuSn by cooling the chip. That is, no void is generated between the impurity diffusion layer on the substrate surface of the submount and the semiconductor material of the semiconductor laser chip. Therefore, heat generated by the semiconductor laser chip in operation can efficiently be radiated from the semiconductor laser chip directly to the Si substrate. As a result, the effects of improving the lifetime of the semiconductor laser chip, improving the reliability of the semiconductor laser device and power savings are obtained.

Moreover, in the submount of the present invention, the structures of the Au layer and the lower layers can be made identical to those of the prior art example (see FIG. 11A). Accordingly, in the stage in which the Au layer (chemically stable) is formed by means of a sputtering apparatus and/or a vapor deposition apparatus in the process of fabricating the submount of the present invention, the substrate that has undergone the layer formation up to the Au layer is once unloaded into the atmosphere. If the substrate is stored, an adjustment becomes possible whether to manufacture the submount of the present invention (submount of a high heat radiation efficiency type) by further forming the Ni layer and the AuSn layer on (the Au layer of) the substrate as occasion demands in view of manufacturing or to manufacture a submount for the Ag paste type by dividing the substrate as it is without forming the AuSn layer. That is, the submount of the present invention can be used in common for the product of the Ag paste type. Moreover, since layer formation up to the AuSn layer is not continuously (without unloading into the atmosphere) performed on the substrate in an identical facility, the facility cost is not increased and the facility control does not become complicated.

In one embodiment of the submount, a light receiving element for monitoring an output of the semiconductor laser chip is fabricated on the substrate surface.

The submount of the present one embodiment is able to monitor the output of the semiconductor laser chip by the light receiving element. That is, the output of the semiconductor laser chip can be controlled on the basis of the output of the light receiving element.

In one embodiment of the submount, the Pt layer, the Au layer, the TiW layer and layers below the TiW layer are formed flat just below the AuSn layer formed on the substrate.

In the submount of the present one embodiment, the Pt layer, the Au layer, the TiW layer and the layers below the TiW layer are formed flat just below the AuSn layer formed on the substrate, and therefore, the whole area of the bonding surface of the semiconductor laser chip can more stably be bonded.

In one embodiment of the submount, the Ni layer, the Au layer, the TiW layer and layers below the TiW layer are formed flat just below the AuSn layer formed on the substrate.

In the submount of the present one embodiment, the Ni layer, the Au layer, the TiW layer and the layers below the TiW layer are formed flat just below the AuSn layer formed on the substrate, and therefore, the whole area of the bonding surface of the semiconductor laser chip can more stably be bonded.

A semiconductor laser device manufacturing method of the present invention for bonding a semiconductor laser chip that has an Au electrode layer to the submount, comprises the steps of:

fusing the AuSn layer by heating the submount within a temperature range of 280° C. to 400° C.;

pressurizing the semiconductor laser chip against the submount so that the Au electrode layer of the semiconductor laser chip is brought in contact with the fused AuSn layer; and

subsequently hardening the AuSn layer by cooling the submount and the semiconductor laser chip.

According to the manufacturing method of the semiconductor laser device of the present invention, the heating temperature for fusing the AuSn layer is not lower than 280° C., and therefore, the AuSn layer can actually be fused (described later in detail). Moreover, the heating temperature for fusing the AuSn layer is not higher than 400° C., thermal damage to the semiconductor laser chip and the penetration of the fused AuSn through the TiW layer can effectively be prevented.

A semiconductor laser device of the present invention has a submount that has a substrate made of a principal material of Si and a semiconductor laser chip mounted on the submount, wherein

an impurity diffusion layer is formed by diffusing an impurity in a region of a substrate surface of the submount above which the semiconductor laser chip is mounted, and

at least a TiW layer, an Au layer, a Pt layer and an AuSn layer exist in order from the impurity diffusion layer side between the impurity diffusion layer of the substrate surface and the semiconductor material layer of the semiconductor laser chip.

In the semiconductor laser device of the present invention, heat generated by the semiconductor laser chip in operation can efficiently be radiated from the semiconductor laser chip directly to the Si substrate. As a result, the effects of improving the lifetime of the semiconductor laser chip, improving the reliability of the semiconductor laser device and power savings are obtained.

In another aspect, a semiconductor laser device of the present invention has a submount that has a substrate made of a principal material of Si and a semiconductor laser chip mounted on the submount, wherein

an impurity diffusion layer is formed by diffusing an impurity in a region of a substrate surface of the submount above which the semiconductor laser chip is mounted, and

at least a TiW layer, an Au layer, an Ni layer and an AuSn layer exist in order from the impurity diffusion layer side between the impurity diffusion layer of the substrate surface and the semiconductor material layer of the semiconductor laser chip.

In the semiconductor laser device of the present invention, heat generated by the semiconductor laser chip in operation can efficiently be radiated from the semiconductor laser chip directly to the Si substrate. As a result, the effects of improving the lifetime of the semiconductor laser chip, improving the reliability of the semiconductor laser device and power savings are obtained.

A hologram laser device of the present invention integrally comprises:

the semiconductor laser device attached to a heat sink portion made of a metal;

a hologram element that passes or diffracts laser light emitted from the semiconductor laser chip toward an optical recording medium;

a light receiving element that receives light returning from the optical recording medium through the hologram element and converts the light into a signal.

In the hologram laser device of the present invention, heat generated by the semiconductor laser chip in operation can efficiently be radiated from the semiconductor laser chip directly to the Si substrate and further to the heat sink portion. As a result, the effects of improving the lifetime of the semiconductor laser chip, improving the reliability of the semiconductor laser device and power savings are obtained.

An optical pickup device of the present invention comprises:

the hologram laser device; and

a holder that supports the optical recording medium so that laser light is emitted from the semiconductor laser chip of the hologram laser device.

In the optical pickup device of the present invention, heat generated by the semiconductor laser chip in operation can efficiently be radiated from the semiconductor laser chip directly to the Si substrate and further to the heat sink portion. As a result, the effects of improving the lifetime of the semiconductor laser chip, improving the reliability of the semiconductor laser device and power savings are obtained.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a view showing the sectional structure of a submount with a built-in light receiving element for monitoring laser light according to one embodiment of the present invention;

FIG. 2 is a view showing the sectional structure of a submount with a built-in light receiving element for monitoring laser light according to another embodiment of the present invention;

FIG. 3 is a view showing the sectional structure of a submount with a built-in light receiving element for monitoring laser light according to further another embodiment of the present invention;

FIG. 4 is a view showing the sectional structure of a submount with a built-in light receiving element for monitoring laser light according to further another embodiment of the present invention;

FIG. 5A is a view showing a planar pattern layout of the submount with the built-in the light receiving element shown in FIGS. 1 and 2;

FIG. 5B is a view showing a device in which a semiconductor laser chip is bonded onto the submount of FIG. 5A;

FIG. 6A is a view showing a heater block for bonding a semiconductor laser chip onto a submount;

FIG. 6B is a view for explaining the step of bonding the semiconductor laser chip onto the submount;

FIG. 7A is a view showing a state in which a semiconductor laser device (device in which the semiconductor laser chip has been bonded to the submount) is mounted on a stem, which is a base component of a hologram laser device, viewed obliquely from above;

FIG. 7B is a view of the device of FIG. 7A viewed from just above;

FIG. 7C is a view of the device of FIG. 7B viewed from a side;

FIG. 7D is a view of the device of FIG. 7B viewed from another side;

FIG. 7E is a view of the device of FIG. 7B viewed from further another side;

FIG. 7F is a view of the device of FIG. 7B viewed from further another side;

FIG. 8 is a flow chart showing a hologram laser device manufacturing method;

FIG. 9A is a view of process step for manufacturing the hologram laser device;

FIG. 9B is a view of process step for manufacturing the hologram laser device;

FIG. 9C is a view of process step for manufacturing the hologram laser device;

FIG. 9D is a view of process step for manufacturing the hologram laser device, viewed from above;

FIG. 9E is a view of the device in FIG. 9D viewed from a side;

FIG. 9F is a view of process step for manufacturing the hologram laser device, viewed from above;

FIG. 9G is a view of the device in FIG. 9F viewed from a side;

FIG. 9H is a view of process step for manufacturing the hologram laser device, viewed from above;

FIG. 9I is a view of the device in FIG. 9H viewed from a side;

FIG. 10 is a phase diagram showing the fusing temperature of an AuSn alloy;

FIG. 11A is a view showing the sectional structure of a conventional submount with a built-in light receiving element for monitoring laser light;

FIG. 11B is a view showing a device in which a semiconductor laser chip is bonded onto the submount shown in FIG. 11A;

FIG. 12 is a view for explaining a problem of the conventional submount with the built-in light receiving element for monitoring laser light;

FIG. 13 is a view for explaining a problem of the conventional submount with the built-in light receiving element for monitoring laser light;

FIG. 14A is a view showing the sectional structure of the conventional submount appropriate for the product of the Ag paste type together with the Ag paste and the semiconductor laser chip; and

FIG. 14B is a view showing a device in which a semiconductor laser chip is bonded onto the submount shown in FIG. 14A;

### DETAILED DESCRIPTION OF THE INVENTION

The present invention will be described in detail below by the embodiments shown in the drawings.

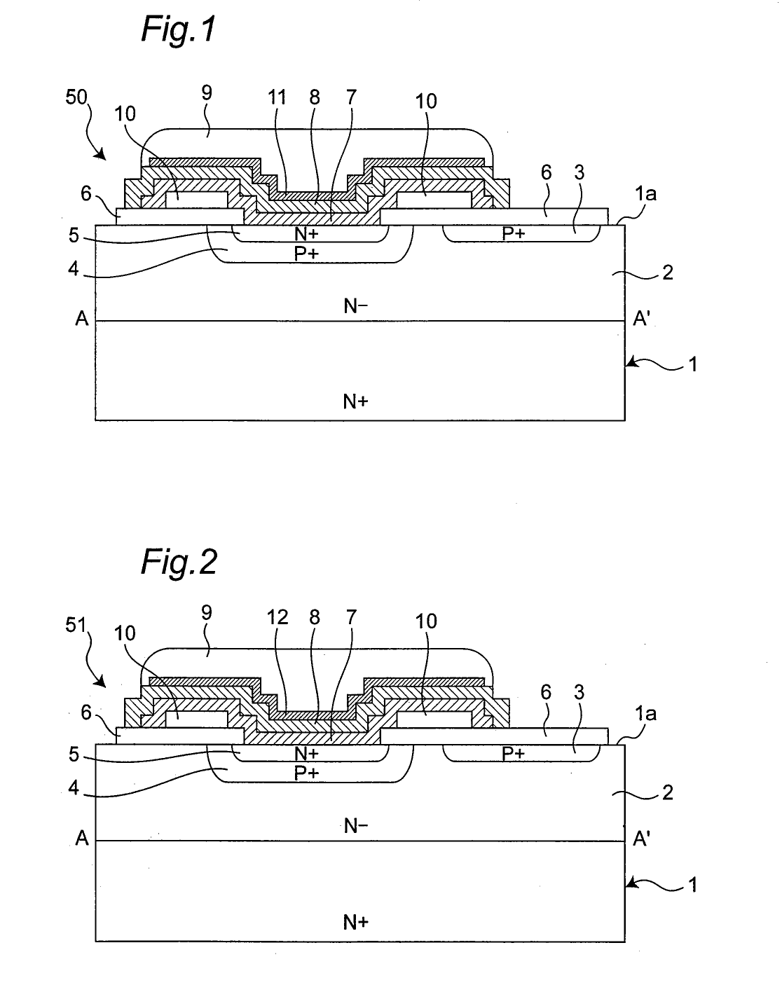

FIG. 1 shows the sectional structure of a submount 50 with a built-in light receiving element for monitoring laser output according to one embodiment. The submount 50 is made of a principal material of an n-type Si substrate 1 (including an n⁻ epitaxial layer 2) and intended to operate as an acceptor that receives heat generated by the semiconductor laser chip and a heat radiation path.

In concrete, the submount 50 has a photodiode 3 (formed by diffusing a p-type impurity) as a light receiving element for monitoring the output of the semiconductor laser chip fabricated on a surface 1a of the n-type Si substrate 1. Moreover, a p⁺ diffusion region 4 and an n⁺ diffusion region 5 for preventing shortcircuit between the semiconductor laser chip and the submount 50 are provided in a region of the surface 1a above which the semiconductor laser chip is to be mounted. The substrate surface 1a is covered with a passivation film 6 obtained by successively layering an SiO₂ film and a silicon nitride film (hereinafter referred to as an “SiN film”) in this order. The passivation film 6 is opened above the regions 4 and 5, and thereafter an alloy layer 7 of titanium and tungsten (hereinafter referred to as a “TiW layer”), an Au layer 8, a Pt layer 11 and an alloy layer of gold and tin (hereinafter referred to as an “AuSn layer”) 9 are successively formed by means of the well-known sputtering apparatus and/or vapor deposition apparatus. It is noted that the AuSn layer 9 is a bonding material for bonding the semiconductor laser chip to be mounted on the layer. The Au layer 8 is provided to keep the surface of the uppermost layer (i.e., Au layer 8) chemically stable in a stage in which the Au layer 8 is formed on the substrate 1 by means of the sputtering apparatus and/or the vapor deposition apparatus in the manufacturing process of the submount 50. The TiW layer 7 is provided as a barrier metal to prevent the diffusion of elements between the p⁺ diffusion region 4 and the n⁺ diffusion region 5 and the AuSn layer 9. The Al layer 10 serves as electric wiring.

The SiO₂ film and the SiN film that constitute the passivation film 6 normally have a thickness within a range of 0.1 μm to 1 μm, which is set through optimization so that the luminous sensitivity of the photodiode 3 is improved. In this example, the thickness of the SiO₂ film is set to 0.45 μm, and the thickness of the SiN film is set to 0.1 μm. The thickness of the Al layer 10 is normally set within a range of 0.2 μm to 5 μm so as to stably have a function as electric wiring. The thickness is set to 1.1 μm in this example. The setting values are similar in other examples described later.

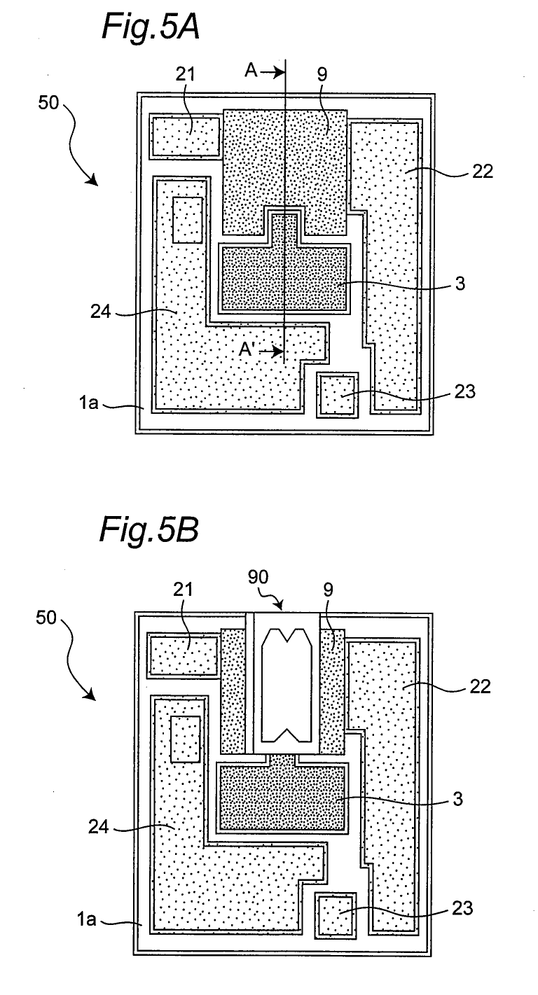

FIG. 5A shows the planar pattern layout of the submount 50, and FIG. 5B shows a state in which a semiconductor laser chip 90 is mounted on the AuSn layer 9 of the submount 50. It is noted that the cross section of the line A-A′ in FIG. 5A corresponds to FIG. 1. As shown in FIG. 5A, cathode electrodes 21, 22 for the semiconductor laser chip 90, an electrode 23 for the photodiode 3 and a common electrode 24 for the semiconductor laser chip 90 and the photodiode 3 are provided on the surface of the submount 50.

As shown in FIG. 1, the Pt layer 11 is interposed between the Au layer 8 and the AuSn layer 9 in the submount 50. The substance of Pt has properties that it scarcely diffuses into the fused AuSn layer 9 and is not fused at the normal heating temperature used to fuse the AuSn layer 9 besides the property of good conformability to the fused AuSn layer 9 and the TiW layer 7. However, diffusion to the fused AuSn layer 9 occurs even in the case of Pt although it is very little in comparison to Au. The velocity (and amount) of diffusion of Pt becomes greater as the heating temperature becomes higher and the amount of AuSn becomes larger. Moreover, Au also diffuses through Pt.

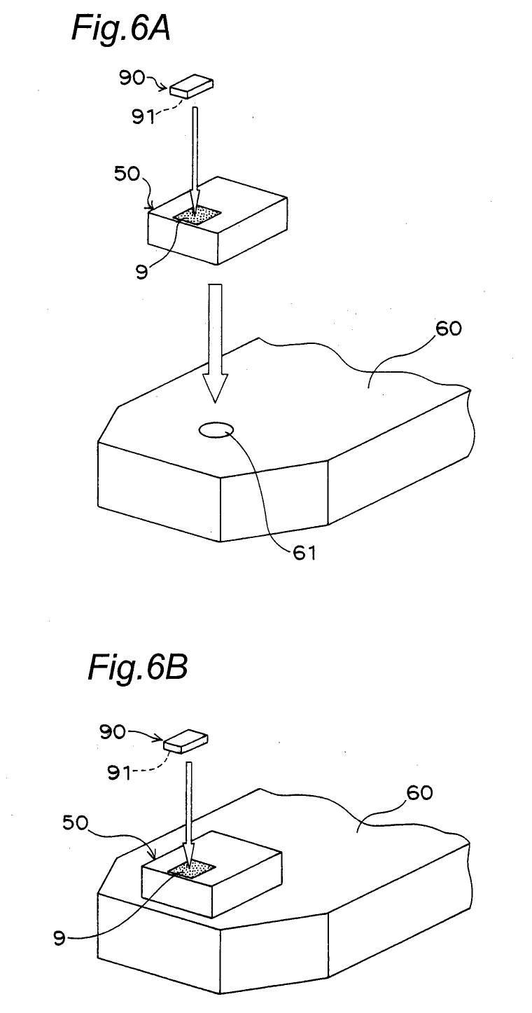

Accordingly, the thickness of the Pt layer 11 is set so that the Pt layer 11 remains in fusing the AuSn layer 9 for bonding the semiconductor laser chip 90 in accordance with the thickness of an Au electrode layer 91 (see FIG. 6A) provided on the lower surface of the semiconductor laser chip 90, the thickness of the Au layer 8 and the thickness and the composition ratio of the AuSn layer 9. In other words, the amount of diffusion of Pt from the Pt layer 11 to the fused AuSn layer 9 (the Au electrode layer 91 provided on the lower surface of the semiconductor laser chip 90 and the Au layer 8 diffuse to the AuSn layer 9) is substantially determined depending on the total amount of Au on the Pt layer 11. Therefore, the thickness of the Pt layer 11 is set so as to exceed the amount of diffusion of Pt.

In this example, the thickness of the Au electrode layer 91 provided on the lower surface of the semiconductor laser chip 90 is about 0.1 μm to 5.0 μm. The thickness of the TiW layer 7 of the submount 50 is 250 nm, and the thickness of the Au layer 8 is about 750 nm. The thickness of the AuSn layer 9 is 1 μm to 5 μm, and its Sn composition ratio is 30 atom %. The thickness of the AuSn layer 9 is synthetically determined by the intended AuSn composition ratio in a state in which AuSn is fused (i.e. in a state in which the Au electrode layer 91 provided on the lower surface of the semiconductor laser chip 90 and the Au layer 8 are diffused and dissolved into the AuSn layer 9), undulations just under the AuSn layer 9 generated depending on the electrode structure and the layer structure of the submount 50 and so on. The thickness of the Pt layer 11 is within a range of 100 nm to 500 nm in this example.

As a result, it is possible to make the Pt layer 11 remain on the TiW layer 7 in fusing the AuSn layer 9 for bonding the semiconductor laser chips 90 (the Au layer 8 also remains between the TiW layer 7 and the Pt layer 11). Since Pt has the property of good conformability to the fused AuSn layer 9, the fused AuSn layer 9 spreads flat without being granulated by surface tension on the remaining Pt layer 11. Therefore, the whole area of the bonding surface of the semiconductor laser chip 90 can stably be bonded by pressurizing the semiconductor laser chip 90 from above and hardening the AuSn by cooling the chip. That is, no void is generated between the n⁺ diffusion layer 5 on the substrate surface 1a of the submount 50 and the semiconductor material of the semiconductor laser chip 90. Therefore, heat generated by the semiconductor laser chip 90 in operation can efficiently be radiated from the semiconductor laser chip 90 directly to the Si substrate 1. As a result, the effects of improving the lifetime of the semiconductor laser chip 90, improving the reliability of the semiconductor laser device and power savings are obtained.

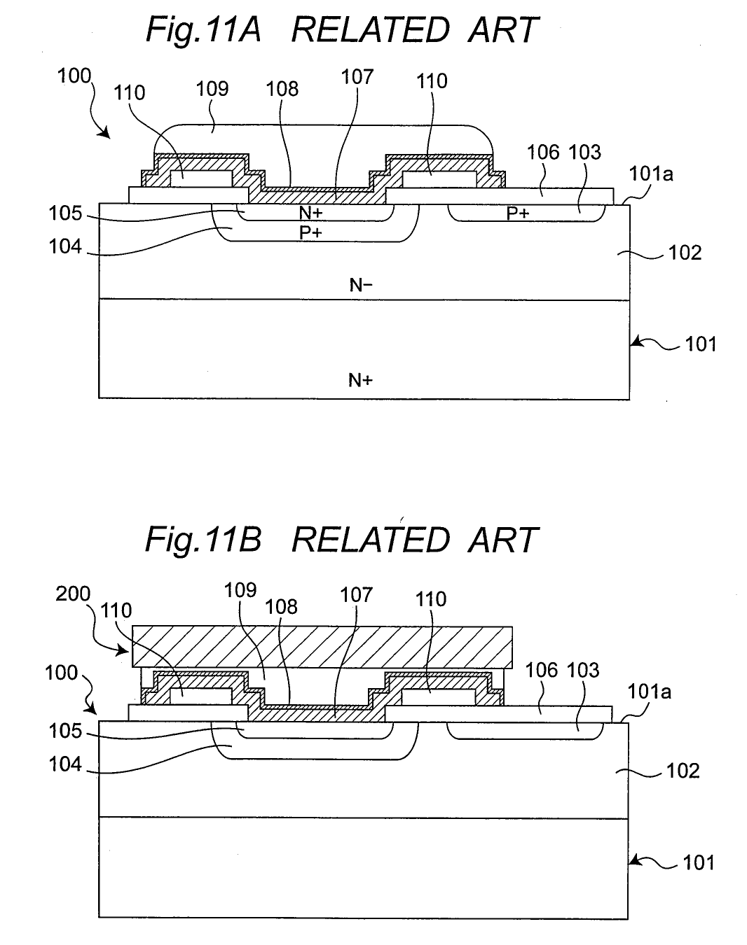

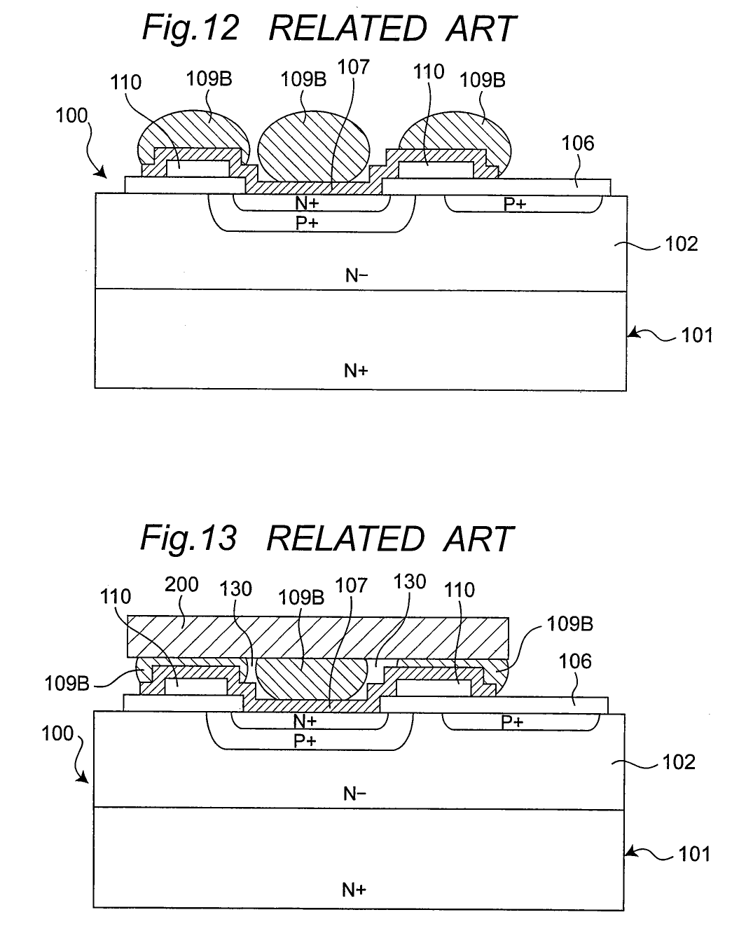

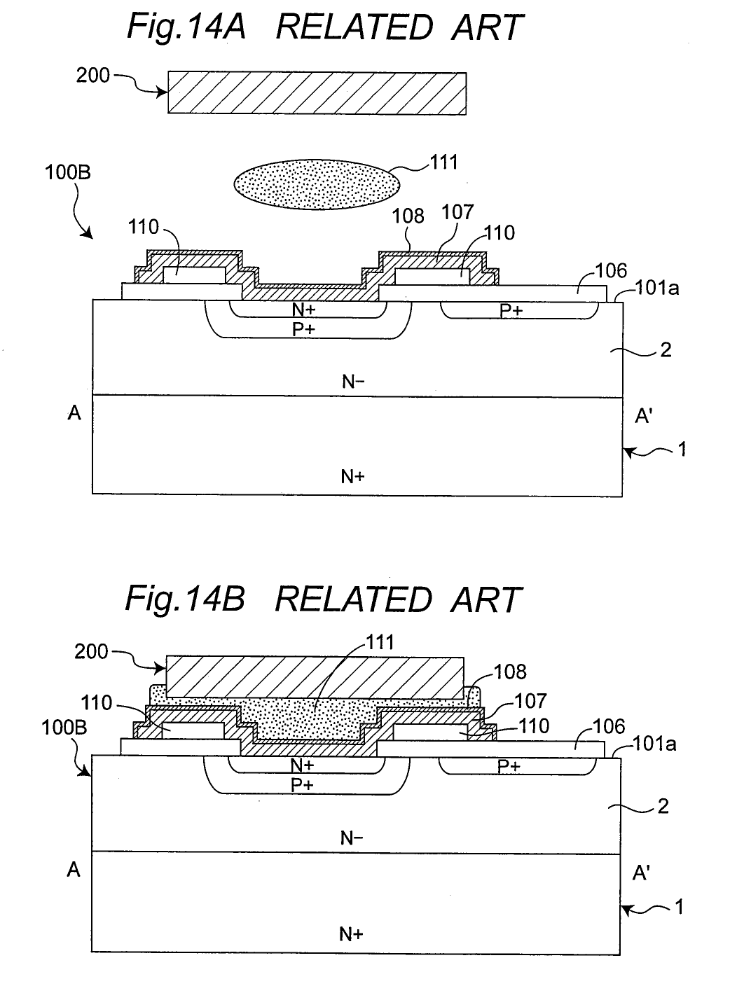

Moreover, in the submount 50, the structures of the Au layer 8 and the lower layers can be made identical to those of the prior art example (see FIG. 11A). Accordingly, in the stage in which the Au layer (chemically stable) 8 is formed by means of the sputtering apparatus and/or the vapor deposition apparatus in the process of fabricating the submount 50, the substrate 1 that has undergone the layer formation up to the Au layer 8 is once unloaded into the atmosphere. If the substrate 1 is stored, an adjustment becomes possible whether to manufacture the submount (submount of a high heat radiation efficiency type) 50 by further forming the Pt layer 11 and the AuSn layer 9 on (the Au layer 8 of) the substrate 1 as occasion demands in view of manufacturing or to manufacture a submount for the Ag paste type by dividing the substrate 1 as it is without forming the AuSn layer. That is, the submount 50 can be used in common for the product of the Ag paste type. Moreover, since layer formation up to the AuSn layer 9 is not continuously (without unloading into the atmosphere) performed on the substrate 1 in an identical facility, the facility cost is not increased and the facility control does not become complicated.

If the thickness of the Pt layer 11 is increased, the material cost is increased. Therefore, taking the cost into account, it is desirable to suppress the thickness of the Pt layer 11 close to the lower limit at which the Pt layer 11 remains in fusing the AuSn layer 9 for bonding the semiconductor laser chips 90.

FIG. 6A shows a heater block 60 for bonding the semiconductor laser chip 90 onto the submount 50. The heater block 60 is well known and made of an Mo steel that has a comparatively high thermal conductivity in order to improve the thermal uniformity. A suction hole 61 for attraction by suction of the submount 50 is provided for the heater block 60.

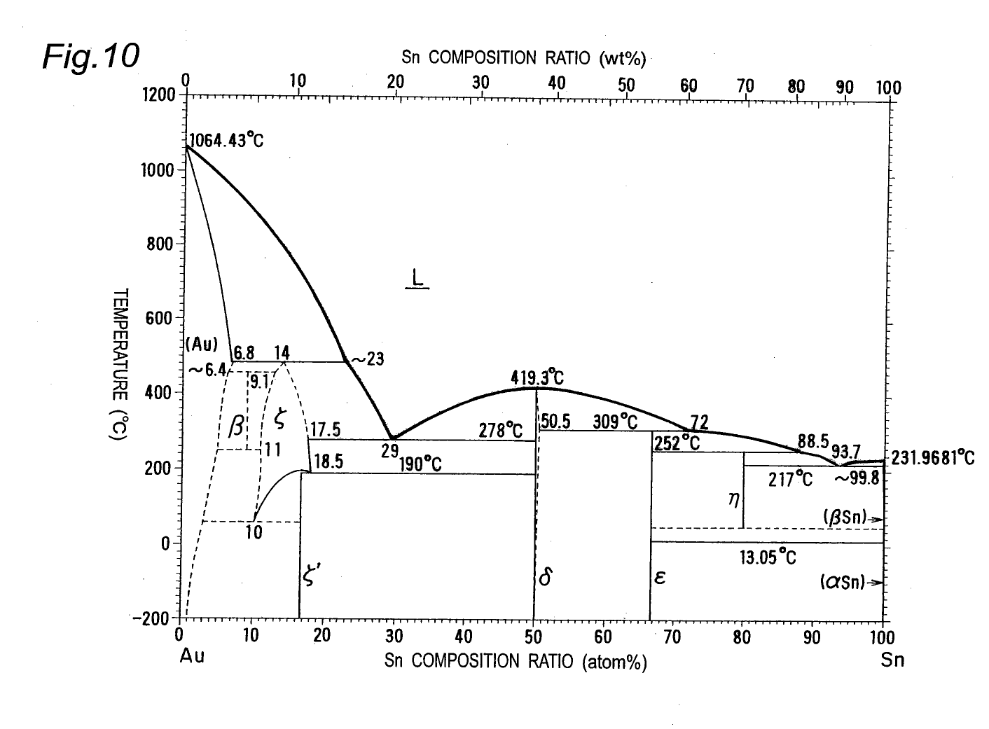

When the bonding step is carried out, the temperature of the heater block 60 is controlled within a range of 280° C. to 400° C. by a temperature controller (not shown). The submount 50 is placed on the suction hole 61, and the submount 50 is sucked and held by a vacuum pump (not shown) through the suction hole 61. In this state, the submount 50 is heated to a temperature within the range of 280° C. to 400° C. If the Sn composition ratio of the AuSn layer 9 is about 30 atom % as shown in the phase diagram of FIG. 10 in this case, the AuSn layer 9 is fused at a temperature of 278° C. (L in the figure indicates the region of liquid phase). In this example, since the heating temperature of the submount 50 is not lower than 280° C., the AuSn layer 9 can actually be fused. Moreover, since the heating temperature is not higher than 400° C., thermal damage to the semiconductor laser chip 90 and the penetration of the fused AuSn through the TiW layer 7 can effectively be prevented. The heating temperature should more preferably be not higher than 380° C. Next, in a state in which the AuSn layer 9 of the submount 50 is fused as shown in FIG. 6B, the semiconductor laser chip 90 is made to closely adhere with pressurization from above. A duration of heating the submount 50 is 0.5 seconds to 1.5 seconds. Subsequently, the submount 50 and the semiconductor laser chip 90 are cooled to harden the AuSn layer 9. As a result, the semiconductor laser chip 90 is bonded onto the AuSn layer 9 of the submount 50.

In the thus-fabricated semiconductor laser device, a state in which at least the TiW layer 7, the Au layer 8, the Pt layer 11 and the AuSn layer 9 exist in order from the n⁺ diffusion region 5 side between the n⁺ diffusion region 5 (see FIG. 1) of the substrate surface 1a of the submount 50 and the semiconductor material layer of the semiconductor laser chip 90 is provided.

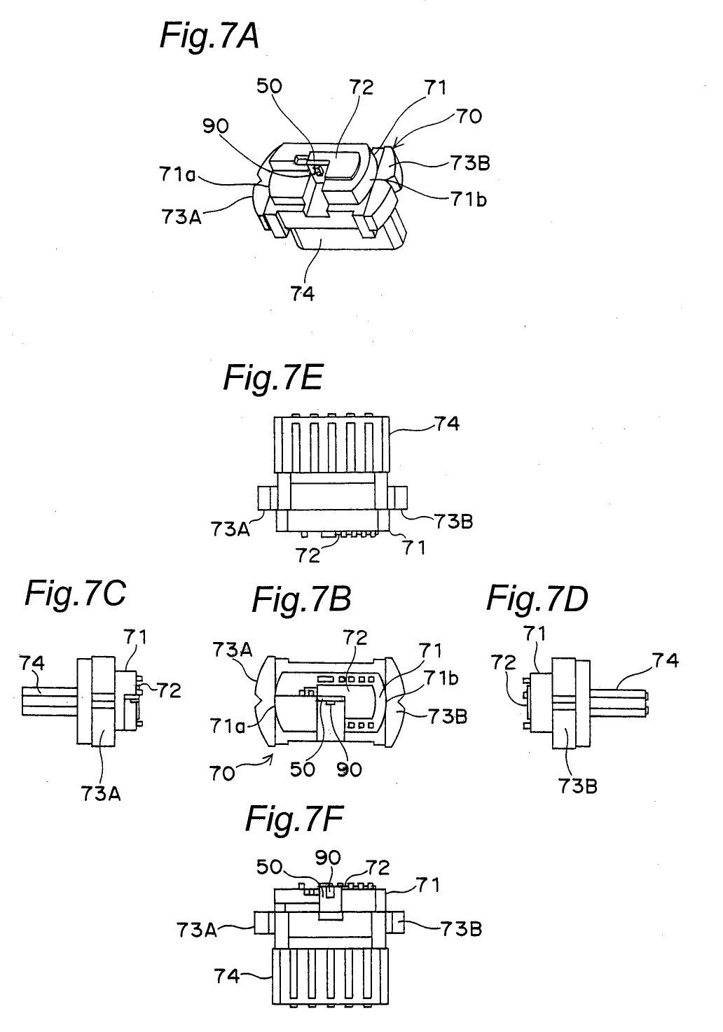

FIG. 7A shows a state in which the semiconductor laser device (device obtained by bonding the semiconductor laser chip 90 to the submount 50) is mounted onto a stem 70, which is a base component of a hologram laser device, viewed obliquely from above. FIG. 7B shows the device of FIG. 7A viewed from just above, and FIGS. 7C through 7F show the device of FIG. 7B viewed from four sides. As shown in these figures, the stem 70 has a projection 71 that has mutually opposed circular arc-shaped side surfaces 71a, 71b and is made of an insulating material, a heat sink portion 72 that is provided generally at the center of the projection 71 and made of a metal, eyelet portions 73A, 73B that integrally connect to the heat sink portion 72 and protrude sideward from the projection 71 and a lead pin portion 74. The semiconductor laser chip 90 is attached to the vertical surface of the heat sink portion 72 together with the submount 50 so that laser light is emitted in the vertical direction in the figure.

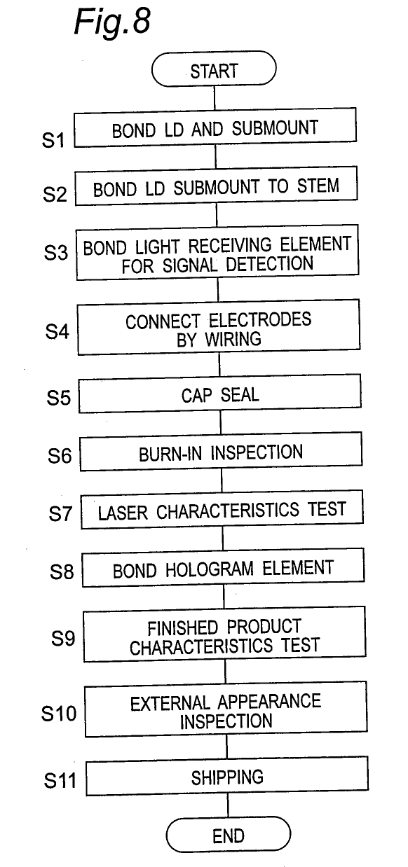

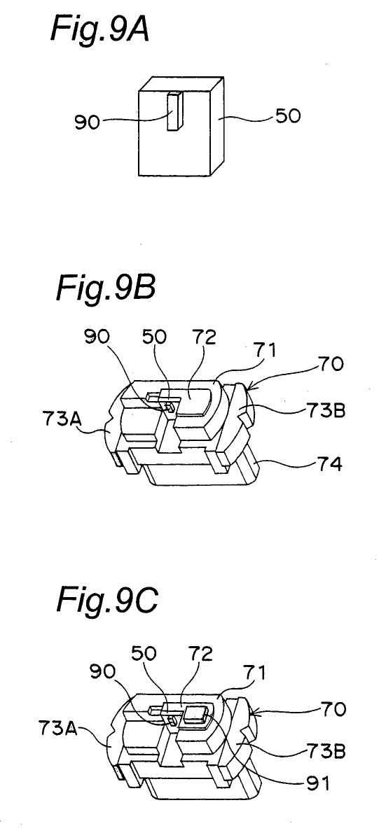

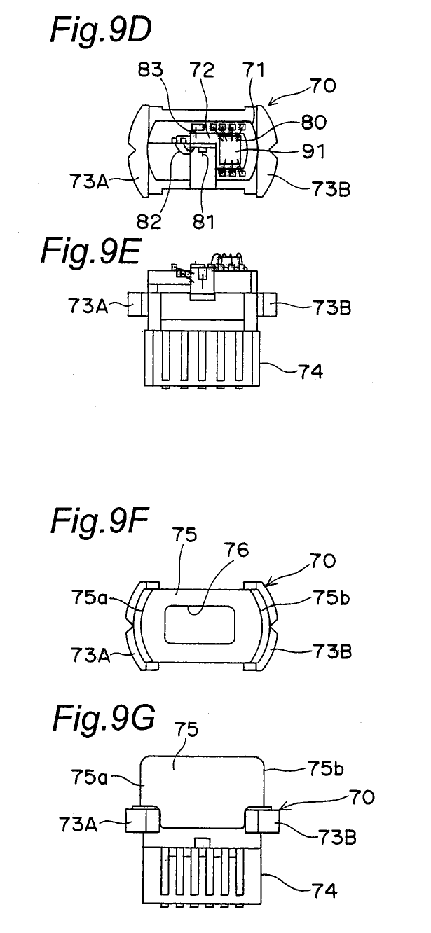

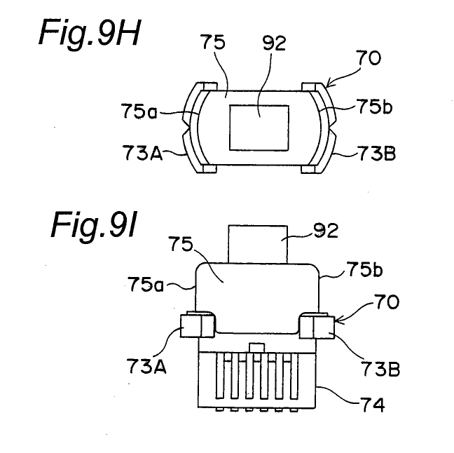

The hologram laser device manufacturing method is described with reference to the step flow of FIG. 8 and the process steps of FIGS. 9A through 9I. As shown in FIG. 9A, a semiconductor laser chip (LD) 90 is bonded to the submount 50 through the bonding step already described (S1). As shown in FIG. 9B, the semiconductor laser chip 90 is bonded together with the submount 50 to the vertical surface of the heat sink portion 72 (S2). The state is identical to the state shown in FIG. 7A. Next, as shown in FIG. 9C, a light receiving element 91 for signal detection is attached onto the heat sink portion 72 (S3). Next, as shown in FIGS. 9D and 9E, wire bonding is performed to provide connections between the electrodes via wires 80, 81, . . . , 83 (S4). In each of the pairs (FIG. 9D, FIG. 9E), (FIG. 9F, FIG. 9G), (FIG. 9H, FIG. 9I), the former shows the device on the way of the process viewed from above, and the latter shows the former viewed from a side. Next, as shown in FIGS. 9F and 9G, a cap seal 75 is attached onto it (S5). The cap seal 75 has mutually opposed circular arc-shaped side surfaces 75a, 75b and are designed to just fit to the projection 71 of the stem 70. A window 76 for letting laser light pass therethrough is provided on the upper surface of the cap seal 75. Subsequently, a burn-in inspection (S6) and a laser characteristics test (S7) are carried out, and thereafter, a hologram element 92 is attached onto the cap seal 75 so as to cover the window 76 as shown in FIGS. 9H and 9I (S8). Subsequently, a finished product characteristics test (S9) and an external appearance inspection (S10) are carried out, and thereafter, the product is shipped as a main component of an optical pickup device (S11).

The optical pickup device has a metal housing to which the hologram laser device manufactured as described above is to be attached and a holder that supports an optical recording media such as DVD or CD (Compact Disc) (the members are not shown because they are general). The eyelet portions 73A, 73B of the hologram laser device are attached to the housing.

The semiconductor laser chip 90 is electrified through the lead pin portion 74 in operation. Laser light emitted upward from the semiconductor laser chip 90 is applied to the optical recording medium through the hologram element 92. Reflected light from the optical recording medium is diffracted through the hologram element 92 and made incident on the light receiving element 91 for signal detection. The output of the light receiving element 91 is outputted through the lead pin portion 74, and a reproduced signal is obtained. Moreover, laser light emitted downward from the semiconductor laser chip 90 is made incident on the photodiode 3 for monitoring fabricated on the submount 50. The output of the semiconductor laser chip 90 is controlled on the basis of the output of the photodiode 3.

Heat generated by the semiconductor laser chip 90 in operation is efficiently radiated from the semiconductor laser chip 90 to the housing through the Si substrate 1 of the submount 50, the heat sink portion 72 of the stem 70, and the eyelet portions 73A, 73B. As a result, the effects of improving the lifetime of the semiconductor laser chip 90, improving the reliability of the semiconductor laser device and power savings are obtained.

FIG. 2 shows the sectional structure of a submount 51 with a built-in light receiving element for monitoring the laser output according to another embodiment. The submount 51 differs in the point that an Ni layer 12 is provided in place of the Pt layer 11 in the submount 50 shown in FIG. 1. Other constituent elements are quite the same as those of the submount 50, and no description is provided therefor with same reference numerals given to them.

The thickness of the Ni layer 12 is set so that the Ni layer 12 remains in fusing the AuSn layer 9 for bonding the semiconductor laser chip 90 in accordance with the thickness of the Au electrode layer 91 provided on the lower surface of the semiconductor laser chip 90, the thickness of the Au layer 8 and the thickness and the composition ratio of the AuSn layer 9 as is in the case of the Pt layer 11. In concrete, the thickness of the Ni layer 12 is within a range of 200 nm to 1000 nm.

The substance of Ni has properties that it scarcely diffuses into the fused AuSn layer 9 and is not fused at the normal heating temperature used to fuse the AuSn layer 9 besides the property of good conformability to the fused AuSn layer 9 and the TiW layer 7 as is in the case of Pt. Therefore, the submount 51 produces operational effects similar to those of the submount 50 shown in FIG. 1. That is, the Ni layer 12 can be made to remain on the TiW layer 7 in fusing the AuSn layer 9 for bonding the semiconductor laser chip 90 (the Au layer 8 also remains between the TiW layer 7 and the Ni layer 12). Since Ni has the property of good conformability to the fused AuSn layer 9, the fused AuSn layer 9 spreads flat without being granulated by surface tension on the remaining Ni layer 12. Therefore, the whole area of the bonding surface of the semiconductor laser chip 90 can stably be bonded by pressurizing the semiconductor laser chip 90 from above and hardening the AuSn by cooling the chip. That is, no void is generated between the n⁺ diffusion region 5 on the substrate surface 1a of the submount 51 and the semiconductor material of the semiconductor laser chip 90. Therefore, heat generated by the semiconductor laser chip 90 in operation can efficiently be radiated from the semiconductor laser chip 90 directly to the Si substrate 1. As a result, the effects of improving the lifetime of the semiconductor laser chip 90, improving the reliability of the semiconductor laser device and power savings are obtained.

Moreover, in the submount 51, the structures of the Au layer 8 and the lower layers can be made identical to those of the prior art example (see FIG. 11A). Accordingly, in the stage in which the Au layer (chemically stable) 8 is formed by means of a sputtering apparatus and/or a vapor deposition apparatus in the process of manufacturing the submount 51, the substrate 1 that has undergone the layer formation up to the Au layer 8 is once unloaded into the atmosphere. If the substrate 1 is stored, an adjustment becomes possible whether to manufacture the submount (submount of a high heat radiation efficiency type) 50 by further forming the Ni layer 12 and the AuSn layer 9 on (the Au layer 8 of) the substrate 1 as occasion demands in view of manufacturing or to manufacture a submount for the Ag paste type by dividing the substrate 1 as it is without forming the AuSn layer. That is, the submount 51 can be used in common for the product of the Ag paste type. Moreover, since layer formation up to the AuSn layer 9 is not continuously (without unloading into the atmosphere) performed on the substrate 1 in an identical facility, the facility cost is not increased and the facility control does not become complicated.

In the semiconductor laser device manufactured by bonding the semiconductor laser chip 90 onto the submount 51, a state in which at least the TiW layer 7, the Au layer 8, the Ni layer 12 and the AuSn layer 9 exist in order from the n⁺ diffusion region 5 side between the n⁺ diffusion region 5 of the substrate surface 1a of the submount 51 and the semiconductor material layer of the semiconductor laser chip 90 is provided. A hologram laser device and an optical pickup device, which include the semiconductor laser device, can produce the same operational effects as the operational effects already described.

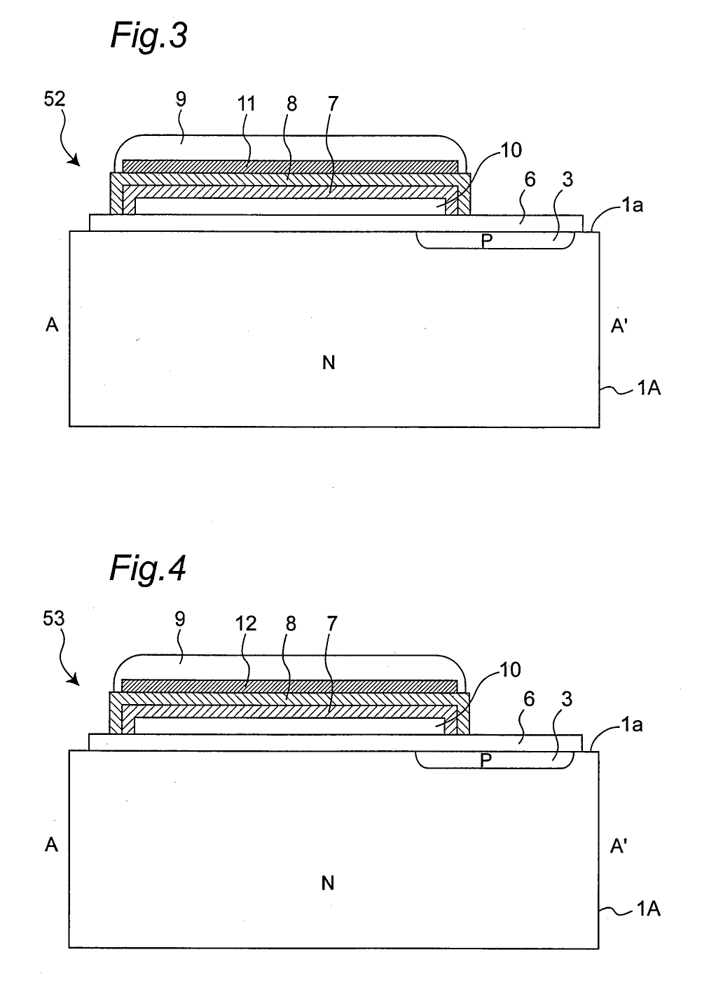

FIG. 3 shows a modification example (the whole body is denoted by reference numeral 52) of the submount 50 of FIG. 1. In the submount 52 of the present modification example, the Pt layer 11, the Au layer 8, the TiW layer 7, and the Al layer 10 and the passivation film 6 below the TiW layer 7 are formed flat just below the AuSn layer 9 formed on the substrate 1A. The submount 52 is able to produce operational effects similar to those of the submount 50 and to further stably bond the whole area of the bonding surface of the semiconductor laser chip 90 since the submount has the flat surface.

Moreover, FIG. 4 shows a modification example (the whole body is denoted by reference numeral 53) of the submount 51 of FIG. 2. In the submount 53 of the present modification example, the Ni layer 12, the Au layer 8, the TiW layer 7, and the Al layer 10 and the passivation film 6 below the TiW layer 7 are formed flat just below the AuSn layer 9 formed on the substrate 1A. The submount 53 is able to produce operational effects similar to those of the submount 51 and to further stably bond the whole area of the bonding surface of the semiconductor laser chip 90 since the submount has the flat surface.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A submount comprising:
a substrate made of a principal material of Si;
an impurity diffusion layer formed by diffusing an impurity in a region of a surface of the substrate above which a semiconductor laser chip is to be mounted;
an Au layer and an AuSn layer that are successively layered on the impurity diffusion layer;
a TiW layer that is interposed between the impurity diffusion layer and the Au layer and prevents diffusion of an element between the impurity diffusion layer and the Au layer and the AuSn layer; and
a Pt layer interposed between the Au layer and the AuSn layer, wherein
the Pt layer has a thickness set so that the Pt layer remains in fusing the AuSn layer for bonding the semiconductor laser chip in accordance with a thickness of the Au electrode layer provided on a lower surface of the semiconductor laser chip, a thickness of the Au layer and a thickness and a composition ratio of the AuSn layer.

2. The submount as claimed in claim 1, wherein
an Ni layer is provided in place of the Pt layer, and
the Ni layer has a thickness set so that the Ni layer remains in fusing the AuSn layer for bonding the semiconductor laser chip in accordance with the thickness of the Au electrode layer provided on the lower surface of the semiconductor laser chip, the thickness of the Au layer and the thickness and the composition ratio of the AuSn layer.

3. The submount as claimed in claim 1, wherein
a light receiving element for monitoring an output of the semiconductor laser chip is fabricated on the substrate surface.

4. The submount as claimed in claim 2, wherein
a light receiving element for monitoring an output of the semiconductor laser chip is fabricated on the substrate surface.

5. The submount as claimed in claim 1, wherein
the Pt layer, the Au layer, the TiW layer and layers below the TiW layer are formed flat just below the AuSn layer formed on the substrate.

6. The submount as claimed in claim 2, wherein
the Ni layer, the Au layer, the TiW layer and layers below the TiW layer are formed flat just below the AuSn layer formed on the substrate.

7. A semiconductor laser device manufacturing method for bonding a semiconductor laser chip that has an Au electrode layer to the submount claimed in claim 1, comprising the steps of:
fusing the AuSn layer by heating the submount within a temperature range of 280° C. to 400° C.;
pressurizing the semiconductor laser chip against the submount so that the Au electrode layer of the semiconductor laser chip is brought in contact with the fused AuSn layer; and
subsequently hardening the AuSn layer by cooling the submount and the semiconductor laser chip.

8. A semiconductor laser device manufacturing method for bonding a semiconductor laser chip that has an Au electrode layer to the submount claimed in claim 2, comprising the steps of:
fusing the AuSn layer by heating the submount within a temperature range of 280° C. to 400° C.;
pressurizing the semiconductor laser chip against the submount so that the Au electrode layer of the semiconductor laser chip is brought in contact with the fused AuSn layer; and
subsequently hardening the AuSn layer by cooling the submount and the semiconductor laser chip.

9. A semiconductor laser device having a submount that has a substrate made of a principal material of Si and a semiconductor laser chip mounted on the submount, wherein
an impurity diffusion layer is formed by diffusing an impurity in a region of a substrate surface of the submount above which the semiconductor laser chip is mounted, and
at least a TiW layer, an Au layer, a Pt layer and an AuSn layer exist in order from the impurity diffusion layer side between the impurity diffusion layer of the substrate surface and the semiconductor material layer of the semiconductor laser chip.

10. A semiconductor laser device having a submount that has a substrate made of a principal material of Si and a semiconductor laser chip mounted on the submount, wherein
an impurity diffusion layer is formed by diffusing an impurity in a region of a substrate surface of the submount above which the semiconductor laser chip is mounted, and
at least a TiW layer, an Au layer, an Ni layer and an AuSn layer exist in order from the impurity diffusion layer side between the impurity diffusion layer of the substrate surface and the semiconductor material layer of the semiconductor laser chip.

11. A hologram laser device integrally comprising:
a semiconductor laser device claimed in claim 9 attached to a heat sink portion made of a metal;
a hologram element that passes or diffracts laser light emitted from the semiconductor laser chip toward an optical recording medium;
a light receiving element that receives light returning from the optical recording medium through the hologram element and converts the light into a signal.

12. A hologram laser device integrally comprising:
a semiconductor laser device claimed in claim 10 attached to a heat sink portion made of a metal;
a hologram element that passes or diffracts laser light emitted from the semiconductor laser chip toward an optical recording medium;
a light receiving element that receives light returning from the optical recording medium through the hologram element and converts the light into a signal.

13. An optical pickup device comprising:
the hologram laser device claimed in claim 11; and
a holder that supports the optical recording medium so that laser light is emitted from the semiconductor laser chip of the hologram laser device.

14. An optical pickup device comprising:
the hologram laser device claimed in claim 12; and
a holder that supports the optical recording medium so that laser light is emitted from the semiconductor laser chip of the hologram laser device.
